(19) United States
(12) Patent Application Publication
(10) Pub. No.: US 2008/0079828 A1
(43) Pub. Date: Apr. 3, 2008

(54) SOLID-STATE IMAGE SENSOR

(75) Inventor: Shinichiro Izawa, Atsugi-City (JP)

Correspondence Address: CANTOR COLBURN, LLP, 20 Church Street, 22nd Floor, Hartford, CT, 06103, US

(73) Assignees: SANYO ELECTRIC CO., LTD., Osaka (JP); SANYO SEMICONDUCTOR CO., LTD., Gunma (JP)

(21) Appl. No.: 11/865,761

(22) Filed: Oct. 2, 2007

(30) Foreign Application Priority Data
Oct. 2, 2006 (JP) JP2006-270345

(51) Int. Cl. H04N 5/335

(52) U.S. Cl. 348/294; 348/E05.091

(57) ABSTRACT

A solid-state image sensor includes photoelectric conversion elements disposed in a matrix pattern. A filter, disposed on a light-receiving surface of each photoelectric conversion element, is one of three visible light filters which have central wavelengths for transmitting mutually different light components or a near-infrared filter having a transmission central frequency in a near-infrared light region. One of the visible light filters and the near-infrared filter are disposed in each column of the matrix pattern formed by the photoelectric conversion elements.

### CROSS-REFERENCE TO RELATED APPLICATIONS

This application claims priority to Japanese Patent Application No. 2006-270345, filed on Oct. 2, 2006.

### BACKGROUND OF THE INVENTION

1. Field of the Invention

The present invention relates to a solid-state image sensor configured to capture a color image.

2. Description of the Related Art

A camera is equipped with an image sensor or an image pickup element, such as a charge coupled device (CCD) or a complementary metal oxide semiconductor (C-MOS). In general, the image pickup element includes a plurality of photoelectric conversion elements disposed in a two-dimensional pattern. Each photoelectric conversion element can convert incident light into an electric signal.

More specifically, a photoelectric conversion element formed on a silicon substrate has photoelectric conversion sensitivity in a visible light region (i.e., in a wavelength range of approximately 380 nm to approximately 650 nm) as well as in a near-infrared light region (i.e., in a wavelength range of approximately 650 nm to approximately 1100 nm).

Furthermore, to capture a color image of an object, the image pickup element includes RGB primary color filters or YMC complementary color filters disposed on a light-receiving surface of the photoelectric conversion elements. The color filters can separate incident light into a plurality of color components and convert the separated light components into electric signals in each wavelength range.

As illustrated in a plan view of FIG. 9, a solid-state image sensor can include a plurality of pixels with RGB primary color filters (or YMC complementary color filters) as well as a certain number of pixels with near-infrared filters disposed on a light-receiving surface thereof. The near-infrared filters are capable of transmitting light having a wavelength component in a near-infrared light (IR) region. The RGB primary color filters and the near-infrared filters are disposed in a mosaic pattern. The solid-state image sensor can capture a color image based on visible light and infrared light.

For example, in an outdoor shooting operation during daytime, the solid-state image sensor can obtain a color image based on output signals of the pixels with color filters. In a shooting operation in a dark room or during nighttime, the solid-state image sensor can obtain a color image based on signals output from the pixels with near-infrared filters.

For example, in a solid-state image sensor including color filters and near-infrared filters, a reference color filter for correction may have a central wavelength capable of transmitting green color components (hereinafter referred to as a green color filter). An exemplary white balance adjustment may use an information charge amount generated by a photoelectric conversion element on which the green color filter is disposed to correct an information charge amount generated by a neighboring photoelectric conversion element on which a color filter having a central wavelength capable of transmitting red or blue light components (hereinafter, referred to as red or blue color filter), so as to reduce the effects of transmission efficiencies of respective color filters.

However, according to the example layout of the color filters and the near-infrared filters illustrated in FIG. 9, each even-number column includes blue color filters and the near-infrared filters only. Namely, each even-number column does not include green color filters. Therefore, the correcting processing on an information charge amount output from an even-number column may not be equalized with the correcting processing on an information charge amount output from an odd-number column. The white balance correction may not be performed properly.

### SUMMARY OF THE INVENTION

According to an aspect of the present invention, a solid-state image sensor includes a plurality of photoelectric conversion elements disposed in a matrix pattern. A filter is disposed on a light-receiving surface of each photoelectric conversion element. The filter is selected from the group consisting of a first visible light filter, a second visible light filter, and a third visible light filter which have central wavelengths for transmitting mutually different light components, or a near-infrared filter having a transmission central frequency in a near-infrared light region. The first visible light filter and the near-infrared filter are disposed in each column of the matrix pattern formed by the photoelectric conversion elements.

### BRIEF DESCRIPTION OF THE DRAWINGS

Exemplary embodiments of the present invention will be described in detail based on the following figures, wherein:

FIG. 1 is a block diagram illustrating a solid-state image sensor according to an embodiment of the present invention;

FIG. 2 is a plan view illustrating an image capturing unit according to an embodiment of the present invention;

FIG. 3 is a cross-sectional view illustrating an image capturing unit according to an embodiment of the present invention;

FIG. 4 is a cross-sectional view illustrating an image capturing unit according to an embodiment of the present invention;

FIG. 5 is a graph illustrating general wavelength dependence in transmission characteristics of a color filter;

FIG. 6 illustrates an example layout of filters according to an embodiment of the present invention;

FIG. 7 illustrates another example layout of filters according to an embodiment of the present invention;

FIG. 8 illustrates another example layout of filters according to an embodiment of the present invention; and

FIG. 9 illustrates a conventional layout of filters.

### DESCRIPTION OF PREFERRED EMBODIMENTS

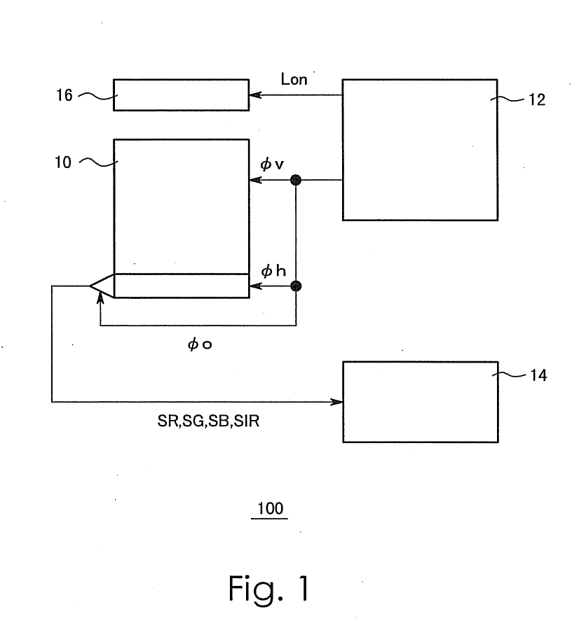

A solid-state imaging apparatus 100 according to an embodiment of the present invention, as illustrated in FIG. 1, includes a solid-state image sensor 10, a clock control unit 12, a signal processing unit 14, and a near-infrared radiation source 16. According to the solid-state imaging apparatus 100, the solid-state image sensor 10 generates an information charge based on incident light. The clock control unit 12 supplies clock signals (φv, φh, and φo) to the solid-state image sensor 10. The solid-state image sensor 10 transfers the information charge in response to a received clock signal. The solid-state image sensor 10 can convert the information charge into electrical signals (SR, SG, SB, and SIR) and successively output the converted signals to the signal processing unit 14. The signal processing unit 14 performs noise removal processing on the input signals.

The solid-state imaging apparatus 100 can capture a color image in an outdoor shooting operation during daytime or in a bright room and also can capture an infrared image in a shooting operation in a dark place or during nighttime. When capturing an infrared image, the clock control unit 12 outputs a light-on signal (Lon) to the near-infrared radiation source 16 in synchronism with shooting timing. The near-infrared radiation source 16 emits infrared light traveling toward an object. The solid-state image sensor 10 forms an image of an object based on reflection light.

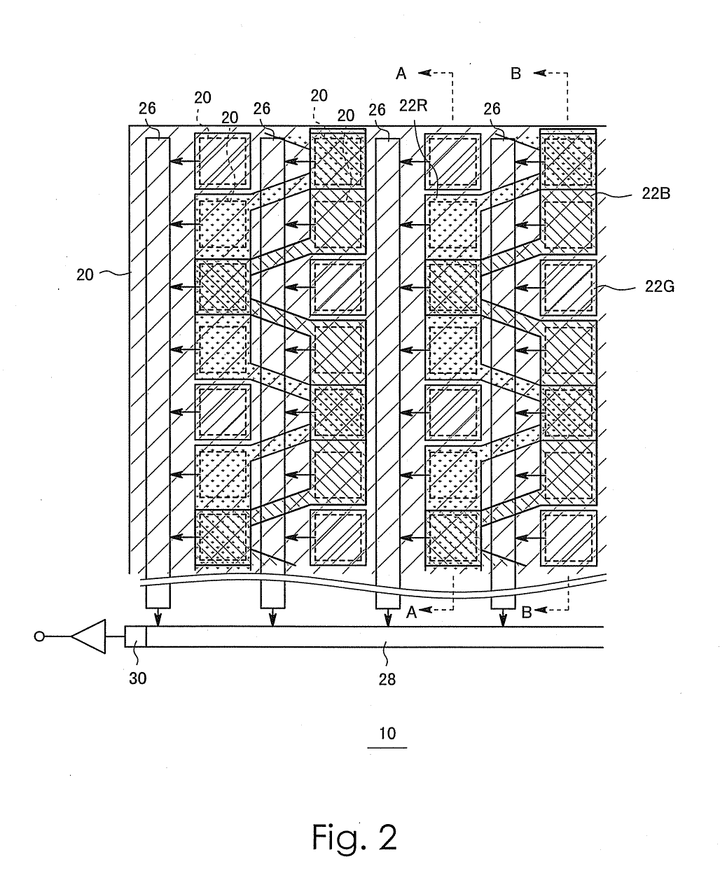

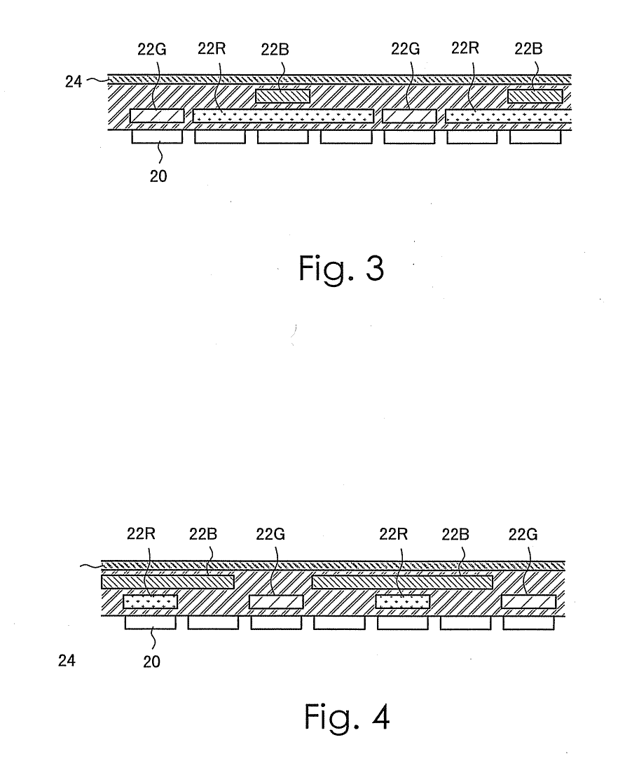

The solid-state image sensor 10, as illustrated in a plan view of FIG. 2 and cross-sectional views of FIGS. 3 and 4, includes a plurality of photoelectric conversion elements 20, color filters 22R, 22G, and 22B, a near-infrared cutoff filter 24, vertical registers 26, a horizontal register 28, and an output unit 30. FIG. 3 illustrates a cross-sectional view taken along a line A-A of FIG. 2. FIG. 4 illustrates a cross-sectional view taken along a line B-B of FIG. 2.

In the present embodiment, the solid-state image sensor 10 includes a plurality of pixels disposed in a matrix pattern. Each pixel includes a photoelectric conversion element 20. The photoelectric conversion element 20 is, for example, a Si photodiode or a CMOS sensor. The photoelectric conversion element 20, connected to the CCD, generates an information charge. Each vertical register 26 transfers the information charge generated by an associated photoelectric conversion element 20 to the horizontal register 28 in a vertical direction (i.e., a downward direction in FIG. 2) in response to a clock signal (φv) supplied from the clock control unit 12. The horizontal register 28 transfers the information charge to the output unit 30 in a horizontal direction (i.e., a leftward direction in FIG. 2) in response to a clock signal (φh) supplied from the clock control unit 12. The output section 30 converts the information charge into a voltage signal and successively outputs the converted signal to the signal processing unit 14.

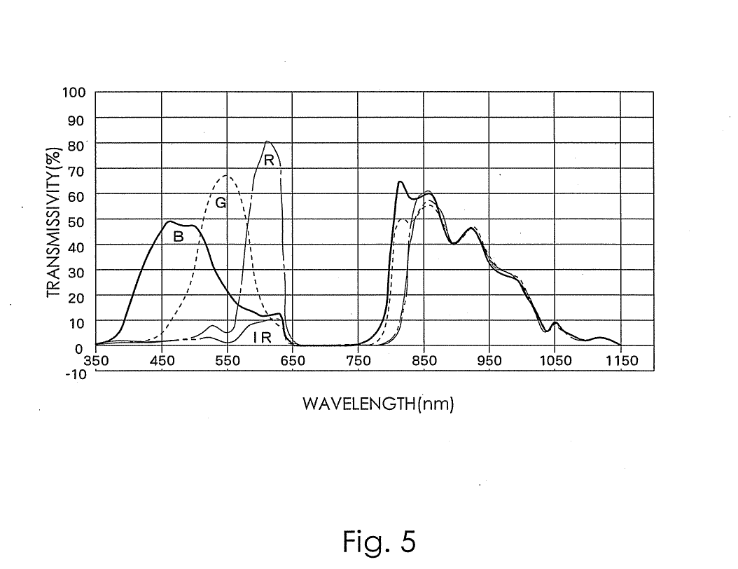

FIG. 5 is a graph illustrating spectral characteristics of an image sensor having band pass filters that do not transmit light components in a wavelength region of approximately 650 nm to approximately 750 nm. A total of four types of filters (i.e., a red color filter 22R, a green color filter 22G, a blue color filter 22B, and a near-infrared filter) are disposed on a light-receiving surface of the pixels disposed in a matrix pattern.

The red color filter 22R transmits light components in a wavelength region corresponding to red color indicated by a line R in FIG. 5. The green color filter 22G transmits light components in a wavelength region corresponding to green color indicated by a line G in FIG. 5. The blue color filter 22B transmits light components in a wavelength region corresponding to blue color indicated by a line B in FIG. 5. The near-infrared filter, arranged by a lamination of the red color filter 22R and the blue color filter 22B, transmits light components in a near-infrared light region. The solid-state image sensor 10 includes a plurality of pixels with four different filters having mutually different transmission characteristics and disposed in a mosaic pattern. In this embodiment, the “mosaic pattern” represents a random layout of different filters disposed in a two-dimensional pattern.

The red color filter 22R has light transmissivity gradually decreasing when the wavelength changes from approximately 350 nm to approximately 420 nm. The red color filter 22R can shield almost all light components in a wavelength region of approximately 420 nm to approximately 500 nm. The transmissivity of the red color filter 22R gradually increases after the wavelength exceeds approximately 500 nm. The red color filter 22R can transmit, at a higher rate, light components whose wavelength is equal to or greater than approximately 550 nm.

The green color filter 22G can shield visible light components in a wavelength range of approximately 360 nm to approximately 420 nm. The transmissivity of the green color filter 22G gradually increases when the wavelength exceeds approximately 420 nm and has a peak at the wavelength equal to approximately 520 nm corresponding to green color. The transmissivity of the green color filter 22G gradually decreases before the wavelength reaches approximately 650 nm and gradually increases after the wavelength exceeds approximately 650 nm. The green color filter 22G can transmit, at a higher rate, near-infrared light components whose wavelength is equal to or greater than approximately 880 nm.

The blue color filter 22B has light transmissivity that increases after the wavelength exceeds approximately 380 nm and has a peak at the wavelength equal to approximately 460 nm corresponding to blue color. The transmissivity of the blue color filter 22B decreases before the wavelength reaches approximately 580 nm and gradually increases after the wavelength exceeds approximately 620 nm. The transmissivity of the blue color filter 22B has a small peak at approximately 690 nm. The blue color filter 22B can transmit, at a higher rate, near-infrared light components whose wavelength is equal to or greater than approximately 800 nm.

The photoelectric conversion element 20 has sensitivity maximized at a wavelength approximately equal to 500 nm. The photoelectric conversion element 20 has sensitivity in a wide range including the visible light region and the infrared region (i.e., in a wavelength region ranging beyond 780 nm and reaching approximately 1100 nm).

In the present embodiment, as illustrated in FIGS. 2 to 4, the red color filter 22R and the blue color filter 22B are laminated and form a near-infrared filter. According to an exemplary structure of the near-infrared filter, the red color filter 22R extends from a pixel on which only a red color filter 22R is provided to a pixel on which a near-infrared filter is provided. The blue color filter 22B extends from a pixel on which only a blue color filter 22B is provided to a pixel on which a near-infrared filter is provided.

More specifically, as illustrated in FIG. 2, the color filters 22R and the color filters 22B are disposed in a zigzag pattern between neighboring columns. The color filter 22R and the color filter 22B are overlapped with each other every four pixels in each column. According to the configuration illustrated in FIGS. 2 to 4, the near-infrared filter can be formed together with the red color filter 22R and the blue color filter 22B in the same manufacturing process.

The near-infrared filter, as indicated by a line IR in FIG. 5, substantially shields visible light components whose wavelength is equal to or less than approximately 580 nm. The transmissivity of the near-infrared filter gradually increases after the wavelength exceeds approximately 580 nm. The near-infrared filter and the blue color filter 22B have similar transmission characteristics in a wavelength range exceeding approximately 690 nm.

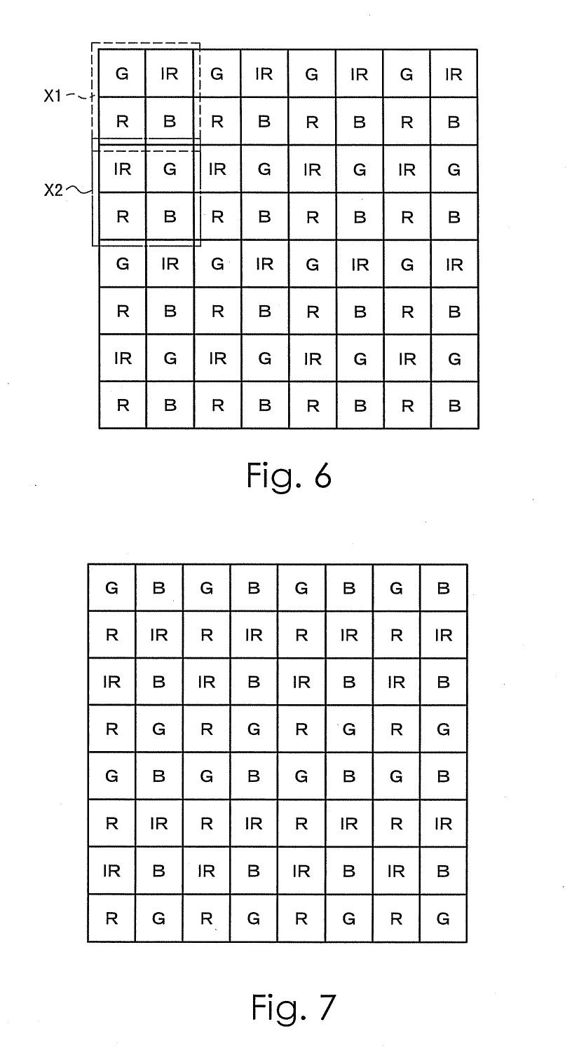

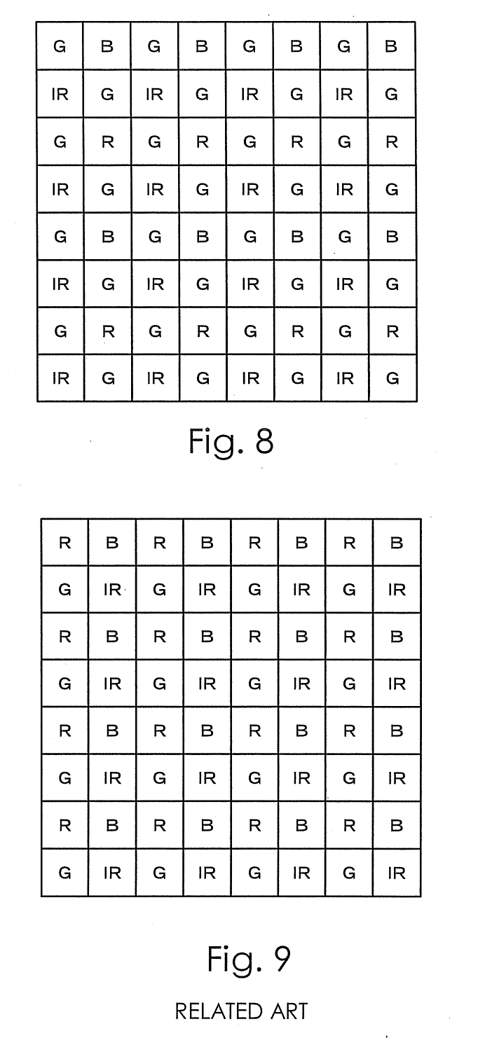

According to the present embodiment, as illustrated in FIG. 6, at least one of the color filters 22R, 22G, and 22B or the near-infrared filter 22IR is provided on a light-receiving surface of each photoelectric conversion element 20. The RGB primary color filters and the near-infrared filters are disposed in a mosaic pattern. In FIG. 6, blocks X1 and X2 are a 2×2 matrix composed of four photoelectric conversion elements 20. Each of the blocks X1 and X2 includes a color filter which serves as a reference for correction. The color filter serving as a reference filter for correction and a near-infrared filter are disposed in each column of the matrix pattern formed by the photoelectric conversion elements (i.e., a column along a transfer direction of the shift register).

The above-described layout including the visible light filters and the near-infrared filter can correct an information charge output from each column based on an information charge output from photoelectric conversion elements in a column on which the first visible light filter is disposed.

According to the example illustrated in FIG. 6, a reference color is green (G). The first row includes green color filters 22G and near-infrared filters 22IR which are alternately arrayed in a direction perpendicular to the transfer direction of the shift register. The second row includes red color filters 22R and blue color filters 22B which are alternately arrayed. The third row includes near-infrared filters 22IR and green color filters 22G, although their positions are offset compared to the array of the first row.

More specifically, the first and third rows are slightly different in that the position of the green color filter G and the position of the near-infrared filter 22IR are switched. The filter layout of the fourth row is identical with the filter layout of the second row. The layout of FIG. 6 includes other filter arrays identical to the above-described first to fourth rows formed repeatedly in the column direction. Thus, the filter layout illustrated in FIG. 6 can uniformly distribute the green color filters 22G (i.e., the reference filter for correction) in each column of the matrix formed by the photoelectric conversion elements 22.

The example layout of the filters illustrated in FIG. 6 constitutes the near-infrared filter 22IR by a lamination of the red color filter 22R and the blue color filter 22B which have the configuration illustrated in FIG. 2.

As illustrated in FIG. 5, the color filter 22G has a central wavelength capable of transmitting green light components. The color filter 22R has a central wavelength capable of transmitting red light components. The color filter 22B has a central wavelength capable of transmitting blue light components. The color filter 22G has a transmission region corresponding to an intermediate region between transmission regions of the color filter 22R and the color filter 22B.

Accordingly, a signal output from the photoelectric conversion elements 20 on which the green color filter 22G (i.e., the reference filer) is disposed can be used to correct a signal output from a neighboring photoelectric conversion element 20. Therefore, the correction of white balance or the like can be performed accurately.

The signal processing unit 14 performs white balance adjustment processing on the color signals. For example, the signal processing unit 14 can adjust the gains for the red color signal SR and the blue color signal SB based on the gain for the green color signal SG. For example, as an exemplary white balance adjustment for the color signals, the signal processing unit 14 can decrease the gain for the red color signal SR by a predetermined amount and increase the gain for the blue color signal SB by a predetermined amount, if the green color signal SG is greater than a predetermined amount. On the other hand, if the green color signal SG is smaller than the predetermined amount, the signal processing unit 14 can equally control the gains for the red color signal SR and the blue color signal SB.

In the present embodiment, the near-infrared cutoff filter 24 is disposed on the light-receiving surface of the pixels. The near-infrared cutoff filter 24 can shield light components with wavelengths in a near-infrared light region. More specifically, it is useful that the near-infrared cutoff filter 24 has filtering characteristics capable of shielding light components whose wavelength is in a wavelength range of approximately 650 nm to approximately 750 nm.

More specifically, it is preferable that the near-infrared cutoff filter 24 has filtering characteristics capable of shielding light components whose wavelength is shorter than a wavelength range of the light emitted from the near-infrared radiation source 16. For example, if the near-infrared radiation source 16 emits light having a peak intensity at the wavelength equal to 850 nm and the near-infrared radiation source 16 has a wavelength dispersion of ±50 nm, it is preferable that the near-infrared cutoff filter 24 has filtering characteristics capable of shielding light components whose wavelength is in a range of approximately 650 nm to approximately 800 nm.

Furthermore, if the near-infrared radiation source 16 emits light having a peak intensity at the wavelength equal to 900 nm and the near-infrared radiation source 16 has a wavelength dispersion of ±50 nm, it is preferable that the near-infrared cutoff filter 24 has filtering characteristics capable of shielding light components whose wavelength is in a range of approximately 650 nm to approximately 850 nm.

The signals SR, SG, and SB output from the solid-state image sensor 10 include noise components (charge) generated by the light components in the infrared region. Accordingly, if these signals SR, SG, and SB are directly used, the solid-state imaging apparatus 100 cannot form a color image having accurate color reproducibility. According to the above-described embodiment, the signal processing unit 14 performs predetermined processing for removing noise components in the near-infrared light region to obtain corrected color signals SR, SG, and SB, based on an output signal SIR obtained from the pixels with the infrared filters provided thereon.

More specifically, as exemplary processing for removing near-infrared light components from the color signals, the signal processing unit 14 can subtract the signal SIR from each of the output signals SR, SG, and SB. In this case, the signal processing unit 14 can equally and properly remove noise components from the primary color signals because the near-infrared cutoff filter 24 can remove the light components in the near-infrared light region (in particular, in a wavelength region from approximately 650 nm to approximately 750 nm) in which the sensitivity is different for each color. Thus, the signal processing unit 14 can accurately realize color reproduction for each of three primary color signals.

FIG. 7 illustrates another example layout of the color filters 22R, 22G, and 22B and the near-infrared filters.22IR according to an embodiment of the present invention. In this case, similar to the above-described layout, a lamination of the color filter 22R and the color filter 22B can constitute the near-infrared filter 22IR. The layout illustrated in FIG. 7 is similar to the layout illustrated in FIG. 6 in that each column includes the green color filters 22G (i.e., reference color filters). Thus, the layout illustrated in FIG. 7 can increase the accuracy in performing correction processing and regenerating colors.

FIG. 8 illustrates another example layout of the color filters 22R, 22G, and 22B and the near-infrared filters 22IR according to an embodiment of the present invention. In this case, similar to the above-described layout, a lamination of the color filter 22R and the color filter 22B can constitute the near-infrared filter 22IR. Each column includes the green color filters 22G (i.e., reference color filters). The layout illustrated in FIG. 7 can increase the accuracy in performing processing for correction and regenerating colors. Forming a near-infrared filter by a lamination of two or more visible light filters in this manner is a simple manufacturing process for a solid-state image sensor and can reduce manufacturing costs.

In the above-described embodiment, the solid-state image sensor 10 can be constituted by a CCD. An exemplary transferring of electric charges can be realized by a CCD of a frame transfer (FT) type, an interline transfer (IT) type, or a frame interline transfer (FIT) type. Furthermore, the photoelectric conversion element 20 according to the present embodiment can be constituted by a CMOS image sensor.

The solid-state image sensor 10 according to the present embodiment includes a photoelectric conversion element block composed of four photoelectric conversion elements 20. Each photoelectric conversion element block includes a red color filter 22R and a blue color filter 22B. The red color filters 22R can be continuously arrayed straight in a column direction of the matrix (i.e., the two-dimensional pattern) formed by the photoelectric conversion elements 20. Similarly, the blue color filters 22B can be continuously arrayed straight in a row direction of the matrix formed by the photoelectric conversion elements 20.

What is claimed is:

1. A solid-state image sensor comprising:
a plurality of photoelectric conversion elements disposed in a matrix pattern; and
a filter disposed on a light-receiving surface of each photoelectric conversion element,
wherein the filter is selected from the group consisting of a first visible light filter, a second visible light filter, and a third visible light filter which have central wavelengths for transmitting mutually different light components, or a near-infrared filter having a transmission central frequency in a near-infrared light region, and
the first visible light filter and the near-infrared filter are disposed in each column of the matrix pattern formed by the photoelectric conversion elements.

2. The solid-state image sensor according to claim 1, wherein the first visible light filter and the near-infrared filter are alternately disposed in each row of the matrix pattern formed by the photoelectric conversion elements.

3. The solid-state image sensor according to claim 1, wherein the first visible light filter, the second visible light filter, and the third visible light filter are primary color filters capable of transmitting red, green, and blue light components respectively, and the first visible light filter is a green color filter.

4. The solid-state image sensor according to claim 2, wherein the first visible light filter, the second visible light filter, and the third visible light filter are primary color filters capable of transmitting red, green, and blue light components respectively, and the first visible light filter is a green color filter.

5. The solid-state image sensor according to claim 3, wherein a lamination of the second visible light filter and the third visible light filter forms the near-infrared filter.

6. The solid-state image sensor according to claim 4, wherein a lamination of the second visible light filter and the third visible light filter forms the near-infrared filter.
